(19) United States
(12) Patent Application Publication
(10) Pub. No.: US 2022/0267889 A1
(43) Pub. Date: Aug. 25, 2022

(54) FABRICATION METHOD OF SILICON NANONEEDLE ARRAY WITH ULTRA-HIGH ASPECT RATIO

(71) Applicant: NANJING UNIVERSITY, Nanjing (CN)

(72) Inventors: Xuecou TU, Nanjing (CN); Mengxin LIU, Nanjing (CN); Lin KANG, Nanjing (CN); Labao ZHANG, Nanjing (CN); Xiaoqing JIA, Nanjing (CN); Qingyuan ZHAO, Nanjing (CN); Jian CHEN, Nanjing (CN); Peiheng WU, Nanjing (CN)

(73) Assignee: NANJING UNIVERSITY, Nanjing (CN)

(21) Appl. No.: 17/596,204

(22) PCT Filed: Oct. 26, 2020
(86) PCT No.: PCT/CN2020/123710

§ 371 Date: Dec. 6, 2021

(30) Foreign Application Priority Data
Oct. 30, 2019 (CN) 201911046950.7

(51) Int. Cl. C23C 14/16; C23C 14/30; C23C 14/02; C23C 14/58

(52) U.S. Cl. CPC C23C 14/16; C23C 14/30; C23C 14/022; C23C 14/5873; B82Y 40/00

(57) ABSTRACT

A fabrication method of a silicon nanoneedle array with ultra-high aspect ratio includes the following steps: spin-coating two photoresist layers of methyl methacrylate (MMA) and polymethyl methacrylate (PMMA) A2 on a silicon substrate; subjecting the silicon substrate coated with the two photoresist layers of MMA and PMMA A2 to electron beam lithography to form a photoresist pattern on the silicon substrate; subjecting the silicon substrate on which the photoresist pattern is formed to electron beam evaporation (EBE) to deposit an Al film layer on the silicon substrate; subjecting the silicon substrate on which the Al film layer is deposited to stripping to obtain an Al film array deposited on the silicon substrate, which provides a mask for the subsequent inductively coupled plasma (ICP) etching process; and subjecting the silicon substrate covered with the Al mask to ICP silicon etching to obtain a silicon nanoneedle array structure.

### CROSS REFERENCE TO THE RELATED APPLICATIONS

This application is the national phase entry of International Application No. PCT/CN2020/123710, filed on Oct. 26, 2020, which is based upon and claims priority to Chinese Patent Application No. 201911046950.7, filed on Oct. 30, 2019, the entire contents of which are incorporated herein by reference.

### TECHNICAL FIELD

The present disclosure relates to the technical field of semiconductors, and in particular to a method for fabricating a silicon nanoneedle array with ultra-high aspect ratio through comprehensive use of electron beam lithography (EBL), electron beam evaporation (EBE), and inductively coupled plasma (ICP).

### BACKGROUND

Nano-scale needles are very important and widely used in the production of biomedical cell probes, single-photon sources, electromagnetic wave absorbers, anti-reflection structures, quantum devices, and the like. For example, in 2015, C. Chiappini et al (Nature Materials, 14 (5), 532-539, 2015) used silicon nanoneedles to deliver nucleic acids in cells. Compared with traditional means, this silicon nanoneedle-based injection technology has the advantages of small trauma, prominent targeting ability, and the like. In 2016, Wen Qiye et al (Chinese patent No. 201611243901.9) disclosed a broadband terahertz wave absorbing material based on a silicon nanoneedle array, which has an absorption rate of 90% for terahertz wave, and overcomes the shortcomings of existing terahertz wave absorbers, such as narrow absorption bandwidth, poor stability, and high manufacturing cost.

At present, there are not many methods for fabricating silicon nanoneedles, and dry etching is a common method. For dry etching of silicon, photoresist is usually used as an etching mask, but this method has many defects. When the positive photoresist polymethyl methacrylate (PMMA) is used as an etching mask, exposed area will inevitably be large, along with long exposure time and poor etching resistance, and it is difficult to achieve an etching depth of more than 5 μm. When the negative photoresist hydrogen silsesquioxane (HSQ) is used as an etching mask, the etching resistance is better than that of PMMA, but a molecular polymer formed after exposure and development is not easy to remove, which will cause contamination to the next process; moreover, HSQ has high price, short shelf life, and poor process stability, and cannot achieve an etching depth of more than 10 μm. Other fabrication methods, such as wet etching, thermal evaporation, and focused ion milling, also have many problems such as complicated process, high fabrication cost, and difficult mass production.

### SUMMARY

An objective of the present disclosure is to provide a fabrication method of a silicon nanoneedle array with ultra-high aspect ratio.

Technical solution to achieve the objective of the present disclosure: A fabrication method of a silicon nanoneedle array with ultra-high aspect ratio is provided, including the following steps:

step 1: spin-coating two photoresist layers of methyl methacrylate (MMA) and PMMA A2 on a silicon substrate;

step 2: subjecting the silicon substrate coated with the two photoresist layers of MMA and PMMA A2 to electron beam lithography to form a photoresist pattern on the silicon substrate;

step 3: subjecting the silicon substrate on which the photoresist pattern is formed to EBE to deposit an Al film layer on the silicon substrate;

step 4: subjecting the silicon substrate on which the Al film layer is deposited to stripping to obtain an Al film array deposited on the silicon substrate, which provides a mask for the subsequent ICP etching process;

step 5: subjecting the silicon substrate covered with the Al mask to ICP silicon etching to obtain a silicon nanoneedle array structure.

Compared with the prior art, the present disclosure has the following obvious advantages: 1) Through the method of the present disclosure, a silicon nanoneedle array structure with ultra-high aspect ratio can be stably fabricated, where a single silicon nanoneedle has a prominent morphology, a smooth sidewall, a minimum tip with a diameter of 10 nm, and an aspect ratio of 1,450. 2) The use of Al as a mask in the present disclosure has the advantages of good etching resistance, stable process, and the like, and can realize the batch production of a silicon nanoneedle array structure with ultra-high aspect ratio at a low cost. 3) The present disclosure can easily obtain silicon nanoneedle array structures with different heights and different tip sizes by changing the layout design and ICP etching parameters.

### BRIEF DESCRIPTION OF THE DRAWINGS

FIG. 1 is a schematic diagram of a process flow for fabricating the silicon nanoneedle array with ultra-high aspect ratio according to the present disclosure.

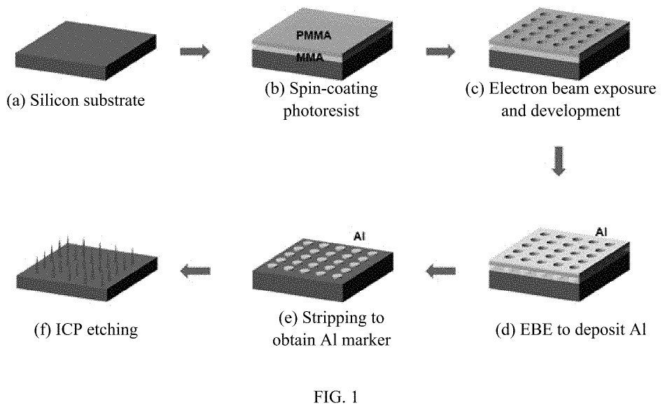

FIG. 2 is a design layout required for the electron beam lithography of the present disclosure.

FIG. 3 is a scanning electron microscopy (SEM) image of the surface of the sample deposited with the Al film layer before stripping according to the present disclosure.

FIG. 4 is an SEM image of the surface of the sample after stripping according to the present disclosure.

FIG. 5 shows SEM images of samples etched under different etching conditions according to the present disclosure.

FIG. 6 shows SEM images of a sample at different etching stages according to the present disclosure.

FIG. 7 is an SEM image of the silicon nanoneedle array fabricated after etching according to the present disclosure.

FIG. 8 is an SEM image of a tip of the silicon nanoneedle fabricated by the present disclosure.

FIG. 9 is an SEM image of the size measurement of the tip of the silicon nanoneedle fabricated by the present disclosure.

### DETAILED DESCRIPTION OF THE EMBODIMENTS

The solution of the present disclosure will be further explained below in conjunction with accompanying drawings and specific examples.

The fabrication method of a silicon nanoneedle array with ultra-high aspect ratio according to the present disclosure mainly includes the following micro- and nano-processing steps:

(1) A pure silicon substrate is subjected to ultrasonic cleaning for 5 min to 8 min successively with acetone, alcohol, and deionized water, then blow-dried with a nitrogen gun to remove residual moisture on the surface, and then observed under an optical microscope to confirm that the surface is clean and has no obvious particles and debris. If the surface of the silicon substrate is not clean enough, the subsequent fabrication of a photoresist structure will be affected.

(2) The silicon substrate is spin-coated with a layer of MMA and then baked on a constant-temperature baking platform to remove residual moisture in the photoresist. Then the silicon substrate is spin-coated with a layer of PMMA A2 and baked in the same manner. According to a large number of experiments, parameters in Table 1 are preferred for the spin-coating and baking of MMA and PMMA A2. Under these parameters, the MMA and PMMA adhesive layers have a moderate thickness, prominent uniformity, and strong adhesion. The double-layer photoresist process used in this step can bring great convenience to the subsequent stripping step.

TABLE 1
EBL conditions

| | | | | | Baking |
|---|---|---|---|---|---|
| | Pre-coating | | Main-coating | | temperature/ |
| Photoresist | r/min | t1/s | r/min | t2/s | time ° C./min |
| MMA | 600 | 5 | 3000 | 60 | 240/4 |
| PMMAA2 | 600 | 5 | 3000 | 80 | 240/4 |

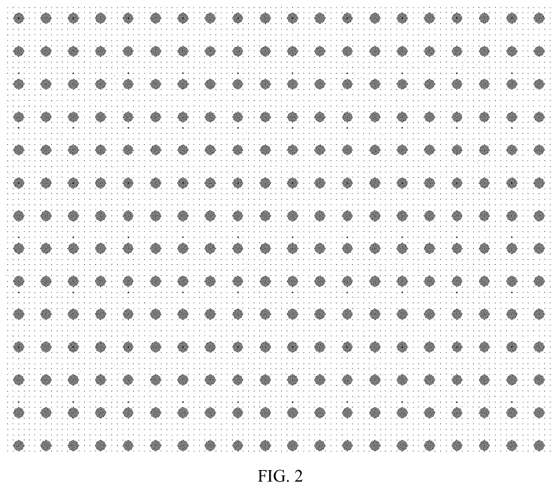

(3) The sample is subjected to electron beam lithography. FIG. 2 shows a layout used for the electron beam lithography of the present disclosure. The layout is made by L-Edit software, and circles in the layout have a radius of 900 nm and a cycle of 5 μm. Although double photoresist layers are used, MMA and PMMA have similar exposure dose, and thus only one exposure step is required. Through various exposure dose tests, the present disclosure finally determines an optimized exposure dose of the electron beam lithography step as 750 μC/cm². At this exposure dose, the layout pattern allows full exposure, and a photoresist pattern obtained after development has high contrast and high quality. The radius of the circles in the layout design can be adjusted to fabricate silicon nanoneedles with different heights, and a distance between centers of the circles can be adjusted to fabricate silicon nanoneedle array structures with different cycles.

(4) A sample obtained after the electron beam lithography is subjected to development for 3 min in a solution of methyl isobutyl ketone (MIBK) and isopropyl alcohol (IPA) in a ratio of 1:3, then subjected to fixation for 1 min in an IPA solution, soaked in deionized water for 10 s, and blow-dried with a nitrogen gun to remove residual moisture on a surface. When a gas gun is used to blow-dry a sample, the gas output of the gas gun should not be too large, thereby avoiding the collapse of the photoresist pattern. Since both MMA and PMMA are positive photoresists, at the exposure dose in step (3), a circular pattern array area exposed by electron beam on the two photoresist layers will be removed after the development and fixation, and the remaining area unexposed by electron beam will be retained.

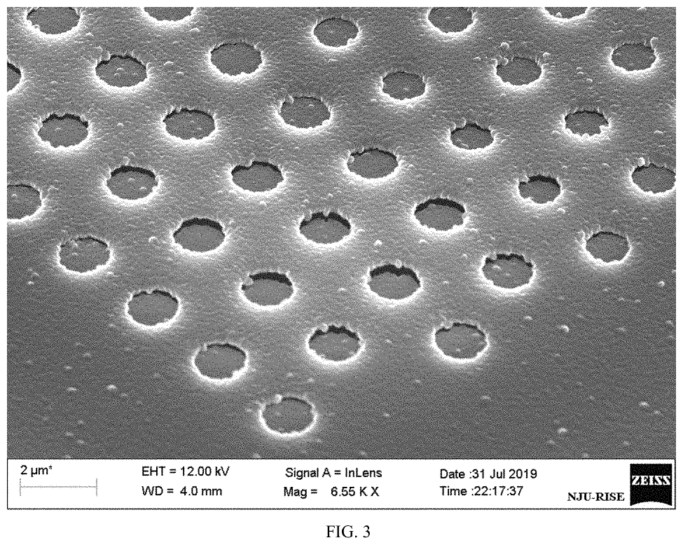

(5) An Al film layer with a thickness of 300 nm to 350 nm is deposited on a sample through EBE. FIG. 3 shows an SEM image of the sample deposited with the Al film layer, where a circular recessed area is the Al film deposited on the silicon substrate, and the remaining area is the Al film deposited on the double photoresist layers.

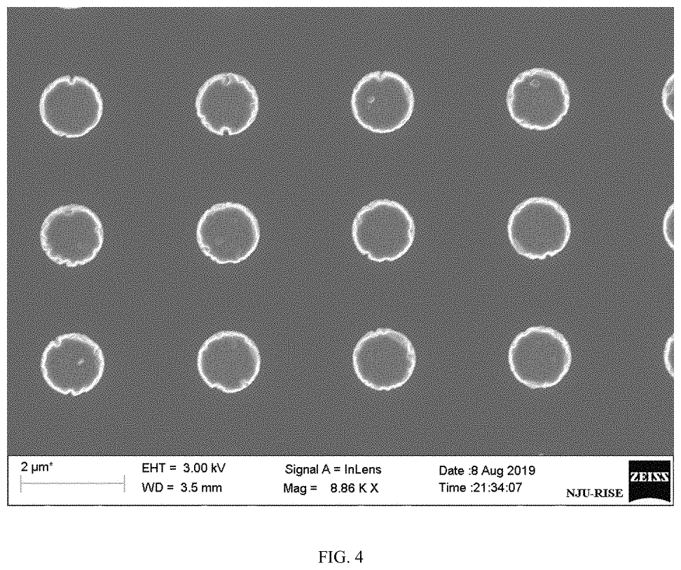

(6) A sample is first immersed in an N-methylpyrrolidone (NMP) solution and heated in a water bath at 80° C. for 60 min, and then placed in acetone, alcohol, and deionized water successively to strip the Al film deposited on the photoresist with an ultrasound machine to finally obtain the circular Al film deposited on the silicon substrate. When the stripping is conducted with the ultrasonic machine, a power should not be too high, thereby preventing the Al deposited on the silicon substrate from falling off. FIG. 4 shows an SEM image of a sample obtained after the stripping step, and it can be seen that only circular Al film arrays are retained on the surface of the silicon substrate, and these Al film arrays will provide desired masks for the subsequent etching step.

(7) A sample covered with circular array Al masks is subjected to ICP silicon etching, and specific etching conditions include gas type, gas flow rate, ICP power, RF power, pressure, temperature, etching time, and the like. During etching, a thin silicon grease layer can be applied to the back of the sample to increase thermal conductivity.

The fabrication of a silicon nanoneedle can be divided into two parts as a whole: the fabrication of a tip structure at the top, and the fabrication of a columnar support structure below the tip. In ICP dry etching, different process parameters will lead to structures with different morphologies, and the present disclosure achieves the fabrication of a designed structure accordingly. In the ICP etching process used in the present disclosure, SF₆ is used as an etching gas, and due to its isotropic etching characteristic showing in ICP dry etching, a proper proportion of C₄F₈ needs to be introduced for passivation.

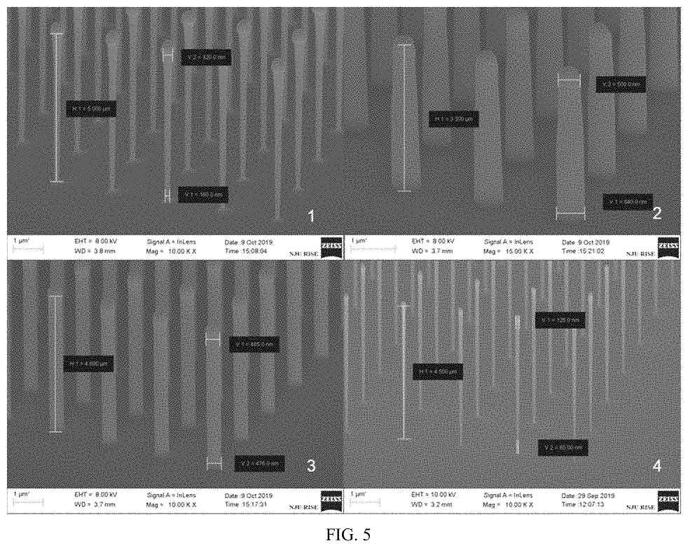

Through a large number of process experiments, it can be known that a flow rate and a proportion of the etching gas show the most significant impact on the morphology of etching. Specifically, when a flow rate ratio of the etching gas to the passivation gas is small, an overall shape of a column appears to have a thin upper part and a thick lower part, and conversely, the overall shape appears to have a thick upper part and a thin lower part. Through a large number of experiments, four sets of stable and representative process parameters are summarized. Table 2 shows data of the four sets of process parameters. Images 1, 2, 3, and 4 in FIG. 5 correspond to the SEM images of the samples obtained under the four sets of ICP etching conditions in Table 2, respectively. By adjusting the etching process parameters, the present disclosure can control an overall shape of a silicon nanoneedle.

TABLE 2
Influence of etching conditions on morphology

| | Etching/passivation | Design | | Etching | Etching | Bottom | Top |
|---|---|---|---|---|---|---|---|
| | gas | diameter | | time | height | diameter | diameter |
| No. | Sccm/Sccm | nm | Overall morphology | min | μm | nm | nm |
| 1 | 32/32 | 500 | Thick upper part and | 9 | 5 | 160 | 320 |
| | | | thin lower part | | | | |
| 2 | 32/50 | 500 | Thin upper part and | 9 | 3.3 | 640 | 500 |
| | | | thick lower part | | | | |
| 3 | 40/50 | 500 | Uniform overall | 9 | 4.6 | 476 | 465 |
| 4 | 40/40 | 200 | Thick upper part and | 9 | 4.5 | 60 | 126 |
| | | | thin lower part | | | | |

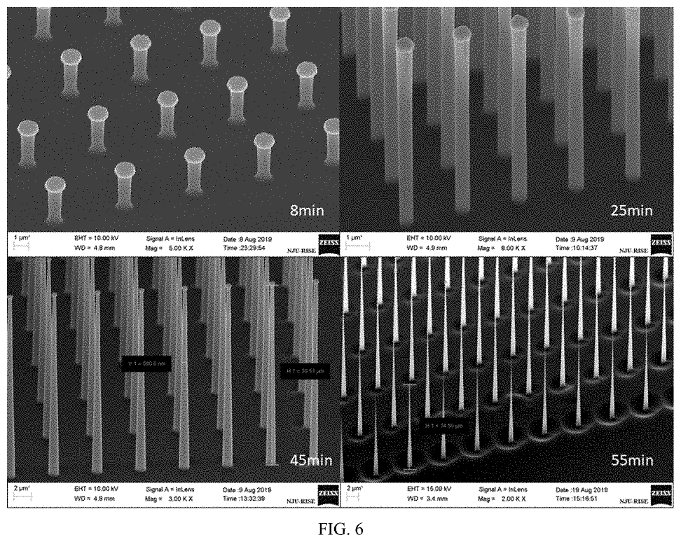

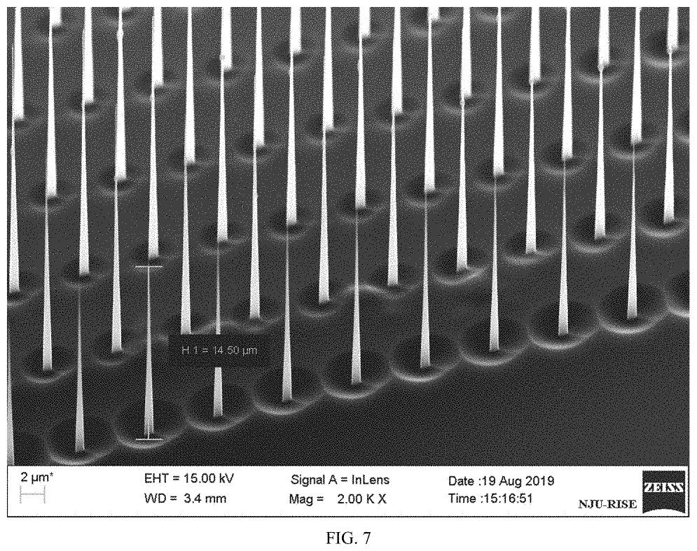

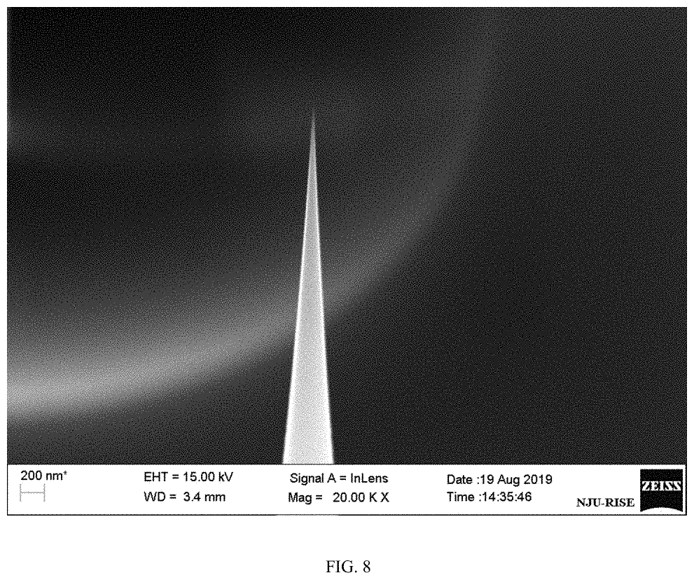

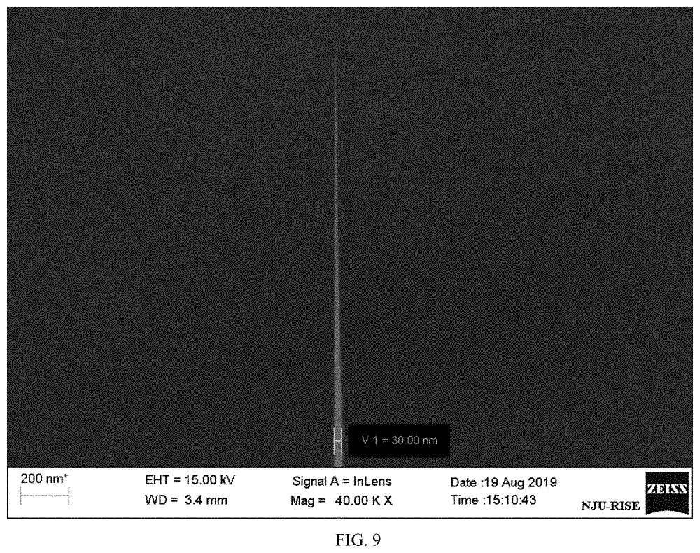

(8) An etched sample is observed under a scanning electron microscope to determine morphology and measure key parameter information. According to results, process parameters are optimized. Through a large number of experiments, the present disclosure determines the optimal process conditions shown in Table 3. FIG. 6 shows SEM images of silicon nanoneedle arrays obtained after 8 min, 25 min, 45 min, and 55 min etching during a fabrication process using the process parameters in Table 3, and it can be seen that there are significant differences in morphologies at different etching stages. FIG. 7 is an SEM image of the silicon nanoneedle array fabricated using the process conditions in Table 3, and it can be seen that the fabricated silicon nanoneedles have a smooth sidewall, a complete morphology, and a uniform overall height of 14.5 μm. FIG. 8 is an SEM image of a tip of the silicon nanoneedle fabricated using the process conditions in Table 3. FIG. 9 is a measurement SEM image of the tip of the silicon nanoneedle fabricated using the process conditions in Table 3, and it can be seen that a minimum size of the tip can reach 10 nm.

TABLE 3
ICP etching conditions

| | Gas flow | ICP power | RF power | Pressure | Temperature | Etching time |
|---|---|---|---|---|---|---|
| Gas | rate Sccm | W | W | mtorr | ° C. | min |
| SF₆ | 32 | 700-900 | 20-30 | 20 | 10 | 55 |
| C₄F₈ | 40 | (750 is the optimal) | (20 is the optimal) | | | |

What is claimed is:

1. A fabrication method of a silicon nanoneedle array with an ultra-high aspect ratio, comprising the following steps:
step 1: spin-coating two photoresist layers of methyl methacrylate (MMA) and polymethyl methacrylate (PMMA) A2 on a silicon substrate;
step 2: subjecting the silicon substrate coated with the two photoresist layers of MMA and PMMA A2 to an electron beam lithography to form a photoresist pattern on the silicon substrate;
step 3: subjecting the silicon substrate formed with the photoresist pattern to an electron beam evaporation (EBE) to deposit an Al film layer on the silicon substrate;
step 4: subjecting the silicon substrate deposited with the Al film layer to stripping to obtain an Al film array deposited on the silicon substrate for providing a mask for an inductively coupled plasma (ICP) etching process;
step 5: subjecting the silicon substrate covered with the Al mask to the ICP silicon etching process to obtain the silicon nanoneedle array.

2. The fabrication method of the silicon nanoneedle array with the ultra-high aspect ratio according to claim 1, wherein before spin-coating two photoresist layers of MMA and PMMA A2 on the silicon substrate, a pure silicon substrate is subjected to an ultrasonic cleaning for 5 min to 8 min successively with acetone, alcohol, and deionized water, and then blow-dried with a nitrogen gun to remove residual moisture on a surface.

3. The fabrication method of the silicon nanoneedle array with the ultra-high aspect ratio according to claim 1, wherein in step 1, the silicon substrate is first spin-coated with a layer of MMA and baked on a constant-temperature baking platform, and then spin-coated with a layer of PMMA A2 and baked.

4. The fabrication method of the silicon nanoneedle array with the ultra-high aspect ratio according to claim 1, wherein in step 2, the electron beam lithography only needs to be conducted once, and an exposure dose for the electron beam lithography is 750 μC/cm².

5. The fabrication method of the silicon nanoneedle array with the ultra-high aspect ratio according to claim 1, wherein the silicon substrate formed with the photoresist pattern obtained after the electron beam lithography is subjected to a development for 3 min in a solution of methyl isobutyl ketone (MIBK) and isopropyl alcohol (IPA) at a ratio of 1:3, then subjected to a fixation for 1 min in an IPA solution, soaked in deionized water for 10 s, taken out and blow-dried with a nitrogen gun to remove residual moisture on a surface, and subjected to the EBE to form the Al film layer.

6. The fabrication method of the silicon nanoneedle array with the ultra-high aspect ratio according to claim 1, wherein in step 3, a thickness of the Al film layer is controlled at 300 nm to 350 nm.

7. The fabrication method of the silicon nanoneedle array with the ultra-high aspect ratio according to claim 1, wherein in step 4, the silicon substrate deposited with the Al film layer is first immersed in an N-methylpyrrolidone (NMP) solution and heated in a water bath at 80° C. for 60 min, and then subjected to ultrasonic stripping in acetone, alcohol, and deionized water successively to finally obtain the Al film array deposited on the silicon substrate.

8. The fabrication method of the silicon nanoneedle array with the ultra-high aspect ratio according to claim 1, wherein in step 5, the ICP silicon etching process is conducted for 55 min at an air pressure of 20 mtorr, a temperature of 10° C., a radio frequency power of 20 W to 30 W, and an ICP power of 700 W to 900 W.

9. The fabrication method of the silicon nanoneedle array with the ultra-high aspect ratio according to claim 1, wherein in step 5, gases used for the ICP silicon etching process are SF₆ and C₄F₈, wherein the SF₆ has a flow rate of 32 Sccm and the C₄F₈ has a flow rate of 40 Sccm.
